(19) United States
(12) Patent Application Publication
(10) Pub. No.: US 2026/0344113 A1
(43) Pub. Date: Oct. 29, 2026

(54) CONVERSION ELEMENT, METHOD FOR PRODUCING A CONVERSION ELEMENT, AND LIGHT EMITTING COMPONENT

(71) Applicant: ams-OSRAM International GmbH, Regensburg (DE)

(72) Inventors: Thomas DREEBEN, Swampscott, MA (US); Florencio GARCIA, North Hampton, NH (US); Alan PIQUETTE, Kensington, NH (US); Jeffery J. SERRE, Peabody, MA (US)

(21) Appl. No.: 19/111,777

(22) PCT Filed: Sep. 6, 2023
(86) PCT No.: PCT/EP2023/074386

§ 371 Date: Mar. 13, 2025

Related U.S. Application Data
(60) Provisional application No. 63/411,436, filed on Sep. 29, 2022.

(51) Int. Cl. H10H 20/01; H10H 20/851

(52) U.S. Cl. CPC H10H 20/0361; H10H 20/8512

(57) ABSTRACT

A conversion element is described. The conversion element comprises a first conversion layer with a first phosphor embedded in a matrix material, said first conversion layer configured to convert electromagnetic radiation of a first wavelength range into electromagnetic radiation of a second wavelength range, and a second conversion layer with a second phosphor, said second conversion layer configured to convert electromagnetic radiation of the first wavelength range into electromagnetic radiation of a third wavelength range. Thereby, an emission maximum of the first phosphor is at higher wavelengths than an emission maximum of the second phosphor.

Furthermore, a method for producing a conversion element and a light emitting component are specified.

A conversion element, a method for producing a conversion element, and a light emitting component are specified.

It is an object to provide a conversion element having an increased efficiency. Furthermore, a simple method for producing a conversion element shall be specified. Additionally, a light emitting component with an increased brightness shall be provided.

According to an embodiment, the conversion element comprises a first conversion layer. The first conversion layer is configured to convert the electromagnetic radiation of a first wavelength range into electromagnetic radiation of a second wavelength range. The first conversion layer comprises a first phosphor embedded in a matrix material. The first phosphor is present, for example, in the form of particles. In particular, the first phosphor is homogeneously distributed in the matrix material. Alternatively, the first phosphor comprises a gradient in the matrix material. That is, on a first side of the first conversion layer the first phosphor has a greater concentration than on a second side of the first conversion layer. For example, the matrix material comprises or consists of an organic polymer, such as a cured resin or a cured polysiloxane. Alternatively, the matrix material is a glass, for example a silica glass or an alumina glass.

According to an embodiment, the conversion element comprises a second conversion layer. The second conversion layer is configured to convert electromagnetic radiation of the first wavelength range into electromagnetic radiation of a third wavelength range. In particular, the second wavelength range comprises longer wavelengths than the third wavelength range. For example, the electromagnetic radiation of the second wavelength range runs unconverted through the second conversion layer. The second conversion layer comprises or consists of a second phosphor.

According to an embodiment of the conversion element, an emission maximum of the first phosphor is at higher wavelengths than an emission maximum of the second phosphor.

According to an embodiment, the conversion element comprises a first conversion layer with a first phosphor embedded in a matrix material, said conversion layer configured to convert electromagnetic radiation of a first wavelength range into electromagnetic radiation of a second wavelength range, and a second conversion layer with a second phosphor, said second conversion layer configured to convert electromagnetic radiation of the first wavelength range into electromagnetic radiation of a third wavelength range wherein an emission maximum of the first phosphor is at higher wavelengths than an emission maximum of the second phosphor.

According to an embodiment of the conversion element, the second wavelength range is in the red spectral range. In particular, the red spectral range comprises the wavelengths between and including 530 nanometers to 765 nanometers. For example, the first phosphor comprises an emission maximum in a range between and including 575 nanometers to 625 nanometers.

According to an embodiment of the conversion element, the third wavelength range is in the yellow spectral range. In particular, the yellow spectral range comprises wavelengths between and including 475 nanometers to 760 nanometers. For example, the second phosphor comprises an emission maximum in a range between and including 500 nanometers to 575 nanometers.

According to an embodiment, the electromagnetic radiation of the second wavelength range and the electromagnetic radiation of the third wavelength range mix to give amber light. In particular, the amber light corresponds to peak wavelengths in a range between and including 590 nanometers to 615 nanometers. For example, the amber light comprises a dominant wavelength of between and including 587 nanometers and 598 nanometers.

According to an embodiment, the conversion element comprises a first conversion layer with a first phosphor embedded in a matrix material, said first conversion layer configured to convert electromagnetic radiation of a first wavelength range into electromagnetic radiation of a second wavelength range, and a second conversion layer with a second phosphor, said second conversion layer configured to convert electromagnetic radiation of the first wavelength range into electromagnetic radiation of a third wavelength range. Thereby, the second wavelength range is in the red spectral range, the third wavelength range is in the yellow spectral range, and the electromagnetic radiation of the second wavelength range and the electromagnetic radiation of the third wavelength range mix to give amber light.

Advantageously, the conversion element is used in radiation emitting components for an automotive turn signal. In particular, the conversion element withstands the temperatures reached in such radiation emitting components. At the same time, a color point of the amber light emitted by the conversion element resides within a specific range and the conversion element gives a high output of electromagnetic radiation measured in lumens.

Other solutions for the production of amber light include a ceramic conversion element or a conversion element comprising a first phosphor and a second phosphor both embedded in a matrix material on a glass substrate. The ceramic conversion element is free of a conversion layer having a phosphor embedded in a matrix material. In particular, the presently described conversion element achieves a higher brightness than the other solutions for the production of amber light, while still having a similar color point. For example, the increased brightness is traced back to a net reduction of photon losses in the conversion element. Furthermore, the presently described conversion element shows a reduction of losses at a mirror of a semiconductor chip if applied in a light-emitting component.

According to an embodiment of the conversion element, the amber light corresponds to a color point within 0.55<Cx<0.6 and 0.4<Cy<0.45 in the CIE 1931 color space.

According to an embodiment of the conversion element, the first wavelength range is in the ultraviolet to blue spectral range. In particular, the ultraviolet spectral range comprises wavelengths between and including 300 nanometers to 400 nanometers, whereas the blue spectral range, for example, comprises wavelengths between and including 400 nanometers and 500 nanometers.

According to an embodiment, the conversion element is configured for full-conversion of the first wavelength range. In other words, the first wavelength range is completely or substantially completely converted into the electromagnetic radiation of the second wavelength range and the electromagnetic radiation of the third wavelength range. This means, that the conversion element substantially only emits the amber light. Substantially in this context means that it is possible that a very small part, in particular at most 5% or at most 1% of the electromagnetic radiation of the first wavelength range runs through the conversion element unconverted. For example, due to the full-conversion of the first wavelength range, the efficiency of the conversion element is increased. This is because, in particular, almost every photon of the first wavelength range is converted in a photon of the second wavelength range or third wavelength range.

According to an embodiment, the conversion layer comprises an adhesive layer between the first conversion layer and the second conversion layer. In particular, the adhesive layer comprises an adhesive polysiloxane, such as a silicone glue. For example, a thickness of the adhesion layer is at most 8 micrometers. Such a thickness of the adhesion layer ensures a reliable connection between the first conversion layer and the second conversion layer while avoiding detrimental effects of using a too thick adhesion layer. Such detrimental effects are, for example, the excessive push out of material of the adhesive layer or defects in the adhesion layer. In particular, a thickness of the adhesion layer is between and including 4 micrometers and 8 micrometers.

According to an embodiment, a thickness of the conversion element is between and including 70 micrometers and 320 micrometers. In particular, a thickness of the first conversion layer is between and including 20 micrometers and 70 micrometers, for example between and including 25 micrometers and 45 micrometers. In particular, a thickness of the second conversion layer is between and including 50 micrometers and 250 micrometers, for example between and including 80 micrometers and 230 micrometers.

Advantageously, the thickness of the conversion element, of the first conversion layer, and of the second conversion layer are chosen such that the full-conversion of the first wavelength range is achieved by the conversion element. Furthermore, with the thickness of the conversion element between and including 70 micrometers and 320 micrometers and especially with the thickness of the second conversion layer between and including 50 micrometers and 250 micrometers the conversion element is self-supporting. This means that there is no need for an additional substrate which gives mechanical stability to the conversion element. Furthermore, a thicker conversion element comprises, in particular, a higher amount of the first phosphor and the second phosphor. In this way, the absorption and/or the scattering in the conversion element is increased.

According to an embodiment of the conversion element, the matrix material comprises or consists of a polysiloxane. In particular, the polysiloxane has the following formula:

[RSiO_{3/2}]ₓ[R₂SiO]_{y}[R₃SiO_{1/2}]_{z}.

[RSiO_{3/2}]represents a T-unit, [R₂SiO] represents a D-unit, and [RSiO_{1/2}]represents an M-unit. In the M-unit, a silicon atom is bonded to one oxygen atom and three carbon atoms. In the D-unit, a silicon atom is bonded to two oxygen atoms and two carbon atoms. In the T-unit, a silicon atom is bonded to three oxygen atoms and one carbon atom. X, y, and z indicate relative proportions of the T-units, the D-units, and M-units respectively. In particular, x is between and including 0.85 and 1.00, y+z is between and including 0 and 0.15, and x+y+z=1.00. Each R is an organic group. In particular, the R of the T-unit, the R of the D-unit, and the R of the M-unit are the same or different. If the R of the T-unit, the R of the D-unit, and the R of the M-unit are different, they are independently selected from another. For example, R is selected from a group consisting of a methyl group and a phenyl group.

It should be noted that the indices x, y, and z represent in particular relative number fractions of the corresponding monomeric groups in the polysiloxane formula. In particular, the indices x, y, and z do not represent the chain length of the polysiloxane. Furthermore, here and in the following the notation of the molecular and structural formulas of polysiloxanes is not meant to suggest that all subunits of one type are grouped together. The formulas are simply meant to show that there are subunits present somewhere in the structure and that the ratio of the subunits is determined by the values of the respective indices. In other words, the polysiloxanes described herein are, for example, not necessarily block copolymers.

In particular, the polysiloxane comprises a three-dimensional network. A backbone of the three-dimensional network comprises, for example, alternating silicon and oxygen atoms. In particular, the backbone of the three-dimensional network only comprises silicon-oxygen bonds and no carbon-carbon bonds.

According to an embodiment of the conversion element, a refractive index of the matrix material, in particular of the polysiloxane, is between and including 1.4 and 1.6.

According to an embodiment of the conversion layer, a siloxane bonding in the polysiloxane is at least 85%, in particular at least 100% T-unit type. In other words, at least 85% of the subunits of the polysiloxane are T-units. The polysiloxane comprising the siloxane bonding of at least 85% advantageously has a high thermal stability. In particular, the more T-units are present in the polysiloxane, the more thermally stable is the first conversion layer.

According to an embodiment of the conversion layer, the polysiloxane is a methyl polysiloxane. Advantageously, the methyl polysiloxane has a high temperature stability and/or shows no or only minor degradation under the influence of electromagnetic radiation, especially in the ultraviolet to blue spectral range.

According to an embodiment of the conversion element, a volume fraction of the first phosphor in the matrix material is between and including 20% and 50%. With such a volume fraction of the first phosphor, the desired color point of the amber light is, in particular, reached.

According to an embodiment of the conversion element, the second conversion layer is a ceramic layer. For example, a ceramic layer comprises or consists of an inorganic material. In particular, the ceramic layer is free of an organic matrix material. Additionally or alternatively, the ceramic layer is sintered and/or comprises pores. In particular, the second conversion layer has a porosity of less than 1 vol %, for example less than 0.1 vol %. In particular the second conversion layer has a porosity between and including 0.02 vol % and 0.1 vol %. The second conversion layer is, for example, an inorganic layer and is free of organic materials. Because of the ceramic second conversion layer it is advantageously possible that the conversion element is self-supporting.

According to an embodiment of the conversion element, the first phosphor is a Eu-based phosphor. In particular, a phosphor comprises an inorganic host material which is doped with an activator element. In the Eu-based phosphor the activator element is Eu.

### For Example, the First Phosphor Is Selected From a Group consisting of:

(AE₁₋ₓEuₓ)₂Al₂Si₂N₆ with 0<x≤0.1, wherein AE is selected from the group consisting of Mg, Ca, Sr, Ba, and combinations thereof,
(A₁₋ₓEuₓ)AlSiN₃ with 0<x≤0.1, wherein AE is selected from the group consisting of Ca, Sr, and combinations thereof,
(AE₁₋ₓEuₓ)₂Si₅N₈ with 0<x≤0.1, wherein AF is selected from the group consisting of Ca, Sr, Ba, and combinations thereof,
(Sr₁₋ₓEuₓ) LiAl₃N₄ with 0<x≤0.1, and combinations thereof.
   Additionally, other red phosphors may also be used as the first phosphor.

According to an embodiment of the conversion element, the second phosphor is a Ce-based phosphor. In other words, the activator element in the second phosphor is Ce.

In particular, the second phosphor has the formula (RE₁₋ₓCeₓ)₃(Al_{1-y}A′_{y})₅O₁₂ with 0<x≤0.1 and 0≤y<1, wherein RE is selected from the group consisting of Y, Lu, Tb, Gd, and combinations thereof and wherein A′ is selected from the group consisting of Sc, Ga, and combinations thereof. However, other yellow phosphors may also be used as the second phosphor. For example, (Y₁₋ₓCeₓ)₃Al₅O₁₂ with 0<x≤0.1 is used as the second phosphor.

According to an embodiment of the conversion element, the second conversion layer comprises or consists of a ceramic layer of the second phosphor. In particular, the second conversion layer comprises or consists of a ceramic layer of Y₃Al₅O₁₂ doped with Ce.

According to an embodiment of the conversion element, the first conversion layer comprises additives selected from the group consisting of thickeners, fillers and combinations thereof. Advantageously, the additives are used to modify the refractive index and/or a thermal conductivity of the first conversion layer. For example, fumed silica is used as additive. In particular, a proportion of the fumed silica in the first matrix material is at most 30 wt %.

According to an embodiment of the conversion element, the first conversion layer comprises traces of a curing agent. These traces result from the formation of the first conversion layer and arise from the curing agent used. “Traces” means that detectable quantities of the curing agent are present in the first conversion layer. However, the detectable quantities in the first conversion layer do not affect performance-related properties of the first conversion layer.

Furthermore, a method for producing a conversion element is specified. In particular, the conversion element described herein is produced by the method. Thus, features and embodiments described for the conversion element also apply to the method and vice versa.

According to an embodiment, the method for producing a conversion element comprises providing a first conversion layer with a first phosphor embedded in a matrix material. The first conversion layer is configured to convert electromagnetic radiation of a first wavelength range into electromagnetic radiation of a second wavelength range.

According to an embodiment of the method, a second conversion layer with a second phosphor is provided. In particular, the second conversion layer is self-supporting such that no further substrate for mechanical stabilization is needed in following steps of the method.

According to an embodiment of the method, the first conversion layer is applied on the second conversion layer.

According to an embodiment of the method, an emission maximum of the first phosphor is at higher wavelengths than an emission maximum of the second phosphor.

According to an embodiment, the method comprises providing a first conversion layer with a first phosphor embedded in a matrix material, said first conversion layer configured to convert electromagnetic radiation of a first wavelength range into electromagnetic radiation of a second wavelength range, providing a second conversion layer with a second phosphor, said second conversion layer configured to convert the electromagnetic radiation of the first wavelength range into electromagnetic radiation of a third wavelength range, and applying the first conversion layer on the second conversion layer. Thereby, an emission maximum of the first phosphor is at higher wavelengths than an emission maximum of the second phosphor. In particular, the method steps are carried out in the order given.

According to an embodiment, the method further comprises applying an adhesive layer on the second conversion layer. In particular, the adhesive layer is applied before the first conversion layer is applied on the second conversion layer. The adhesive layer is, in particular, applied by spraying, dispensing, or casting. For example, the adhesive layer is arranged between the first conversion layer and the second conversion layer after the first conversion layer is applied on the second conversion layer.

According to an embodiment of the method, providing the first conversion layer comprises providing a mixture of a precursor of a matrix material and a first phosphor and curing the mixture to form the first conversion layer. In particular, before curing, the mixture is applied on a substrate. For example, the substrate is a thin plastic foil. Alternatively, the mixture is applied on the second conversion layer.

In particular, the mixture further comprises additives such as thickeners and/or fillers. For example, the mixture further comprises fumed silica. In particular, the precursor of the matrix material is a precursor for a polysiloxane. The precursor of the matrix material is particularly liquid. This results in a mixture which is, for example, a suspension or a slurry.

In particular, during curing, the precursor of the matrix material polymerizes such that the matrix material is formed. Due to the polymerization, the precursor of the matrix material solidifies such that a stable first conversion layer is formed.

According to an embodiment of the method, providing the first conversion layer and applying the first conversion layer are performed simultaneously. In particular, this means that the mixture of the first phosphor and the precursor of the matrix material is applied on the second conversion layer and after applying the mixture on the second conversion layer, the mixture is cured to form the first conversion layer.

According to an embodiment of the method, a curing agent is added to the mixture before curing the mixture. For example, the curing agent is added before applying the mixture on the second conversion layer or the substrate. In particular, the curing agent is a catalyst or a hardener. For example, an amount of the curing agent between and including 0.05 wt % and 5 wt % with respect to an amount of the precursor of the matrix material is added to the mixture. The curing agent is, in particular, selected from the group consisting of titanium alkoxides, amine-containing bases, and combinations thereof. According to an embodiment of the method, the mixture is applied using spraying, dispensing, or casting.

According to an embodiment of the method, the matrix material is a cured polysiloxane. In particular, the precursor of the matrix material is a polysiloxane.

According to an embodiment of the method, the precursor of the matrix material is a methyl methoxy polysiloxane. In particular, a methoxy content of the methyl methoxy polysiloxane is between and including 20 vol % and 50 vol %, for example between and including 30 vols and 40 vol %. Curing the methyl methoxy polysiloxane leads, for example, to the formation of a methyl polysiloxane.

According to an embodiment of the method, a plurality of conversion elements are produced. For this, the second conversion layer is provided in the form of a wafer and after curing of the mixture, the wafer is singulated into individual conversion elements.

According to an embodiment of the method, a size of the second conversion layer provided corresponds to a size of the finally produced conversion element. In particular, the term “size” in this context means a size of the second conversion layer and the conversion element seen in top view. For example, the size is a dimension of a main extension area of the conversion element and/or the second conversion layer.

Furthermore, a light emitting component is specified. In particular, the light emitting component comprises a conversion element described herein. Thus, features and embodiments described in combination with the conversion element and the method for producing a conversion element also apply to the light emitting component and vice versa.

According to an embodiment, the light emitting component comprises a semiconductor chip. The semiconductor chip is configured to emit electromagnetic radiation of a first wavelength range through a radiation exit surface. In particular, the semiconductor chip comprises an epitaxially grown semiconductor layer sequence with an active region. The active region is configured to generate the electromagnetic radiation of the first wavelength range.

According to an embodiment, the light emitting component further comprises a conversion element described herein. The conversion element comprises a first conversion layer with a first phosphor in a matrix material and a second conversion layer with a second phosphor.

According to an embodiment of the light emitting component, the conversion element is arranged on the radiation exit surface. In particular, the conversion element is glued on the radiation exit surface. That is a layer of glue is arranged between the conversion layer and the radiation exit surface of the semiconductor chip.

According to an embodiment, the light emitting component comprises a semiconductor chip configured to emit electromagnetic radiation of a first wavelength range through a radiation exit surface and a conversion element described herein comprising a first conversion layer and a second conversion layer. Thereby, the conversion element is arranged on the radiation exit surface.

In particular, the conversion element converts electromagnetic radiation of the first wavelength range into electromagnetic radiation of a second wavelength range and electromagnetic radiation of a third wavelength range. The electromagnetic radiation of the second wavelength range and the electromagnetic radiation of the third wavelength range mix to give amber light. Thus, the light emitting component emits amber light. Therefore, the light emitting component may be applied in an automotive turn signal.

Advantageously, the light emitting component with the conversion element described herein has a higher brightness compared to light emitting components with other conversion elements. This is because losses at the semiconductor chip associated with back scattering, backward-facing emission, and total internal reflection, losses at converter extremities associated with a higher converter thickness and photons travelling horizontally, and/or conversion losses associated with a Stokes shift and a quantum efficiency of the conversion element are, in particular, at least reduced. For example, converter extremities are a reflective resin with TiO₂, pads of the semiconductor chip, and a base of the semiconductor chip.

According to an embodiment of the light emitting component, the first conversion layer is arranged closer to the radiation exit surface of the semiconductor chip than the second conversion layer. In other words, the first conversion layer is arranged between the second conversion layer and the semiconductor chip.

According to an embodiment, the light emitting component comprises a conversion efficiency of at least 205 lumens/(W optical blue). The conversion efficiency is a fraction with a brightness of a light emitting component, given in lumens, in the numerator. In the denominator the power of the electromagnetic radiation emitted by the semiconductor chip of the light emitting component into air is given in Watts. The higher the conversion efficiency, the brighter and more efficient is the light emitting component.

Advantageous embodiments and developments of the conversion element, the method for producing a conversion element, the radiation emitting device and the method for producing a radiation emitting device will become apparent from the exemplary embodiments described below in conjunction with the figures.

In the figures:

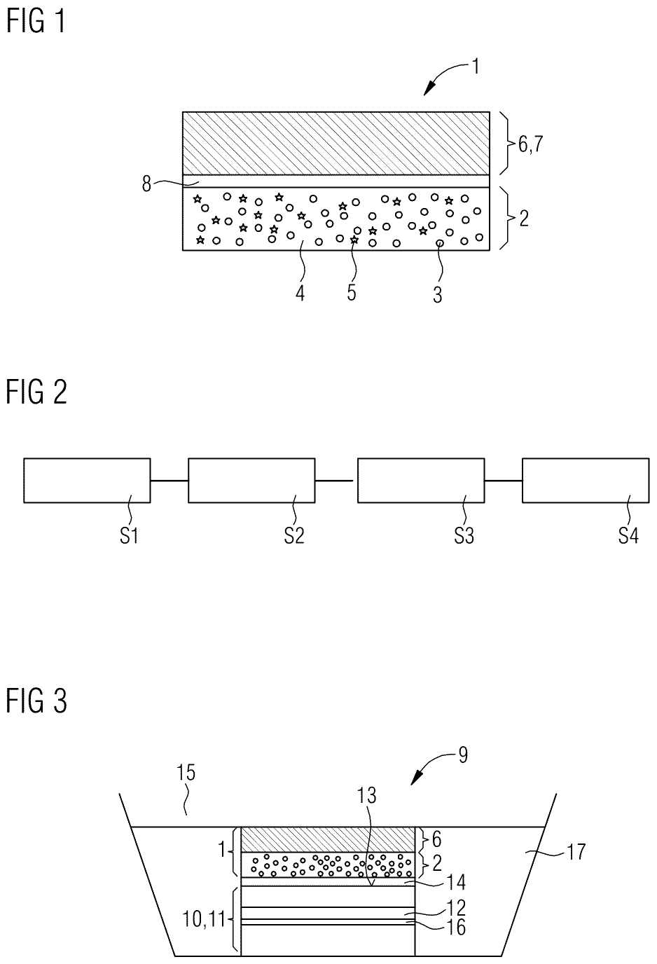

FIG. 1 shows a schematic sectional view of a conversion element according to an exemplary embodiment.

FIG. 2 schematically shows steps of a method for producing a conversion element.

FIG. 3 shows a schematic sectional view of a light emitting component according to an exemplary embodiment.

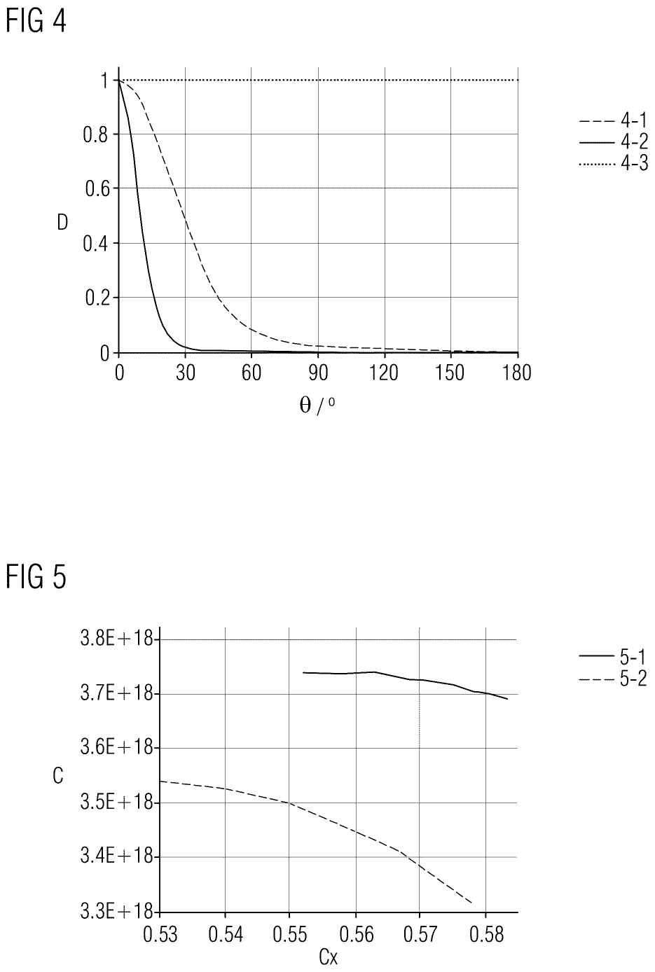

FIG. 4 shows an angular distribution of photons inside a conversion element.

FIG. 5 shows a simulation of a converted light depending on Cx according to an exemplary embodiment and a comparative example.

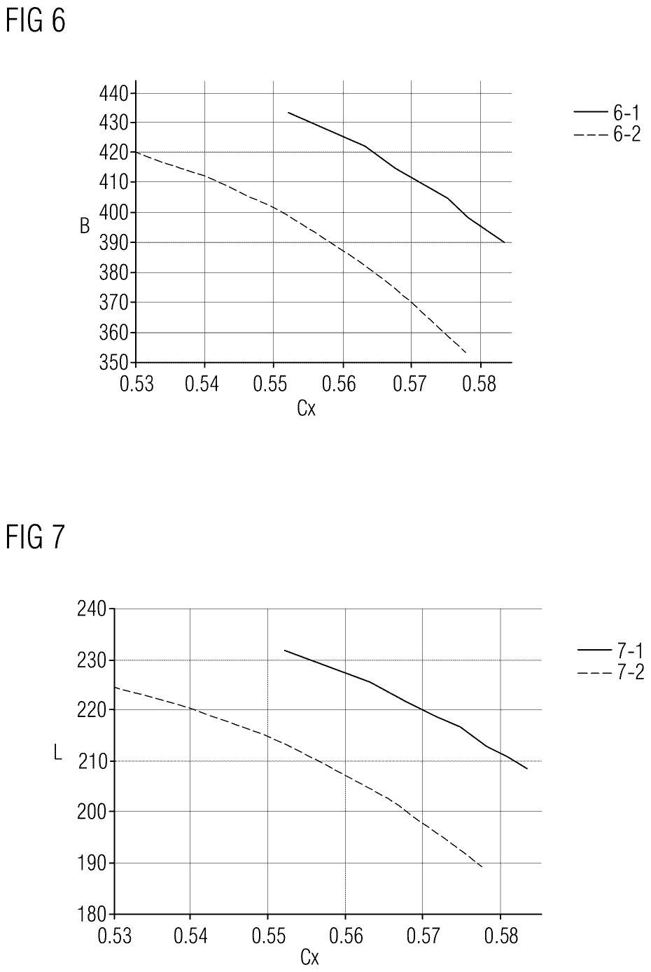

FIG. 6 shows a simulation of a brightness depending on Cx according to an exemplary embodiment and a comparative example.

FIG. 7 shows a simulation of a conversion efficiency depending on Cx according to an exemplary embodiment and a comparative example.

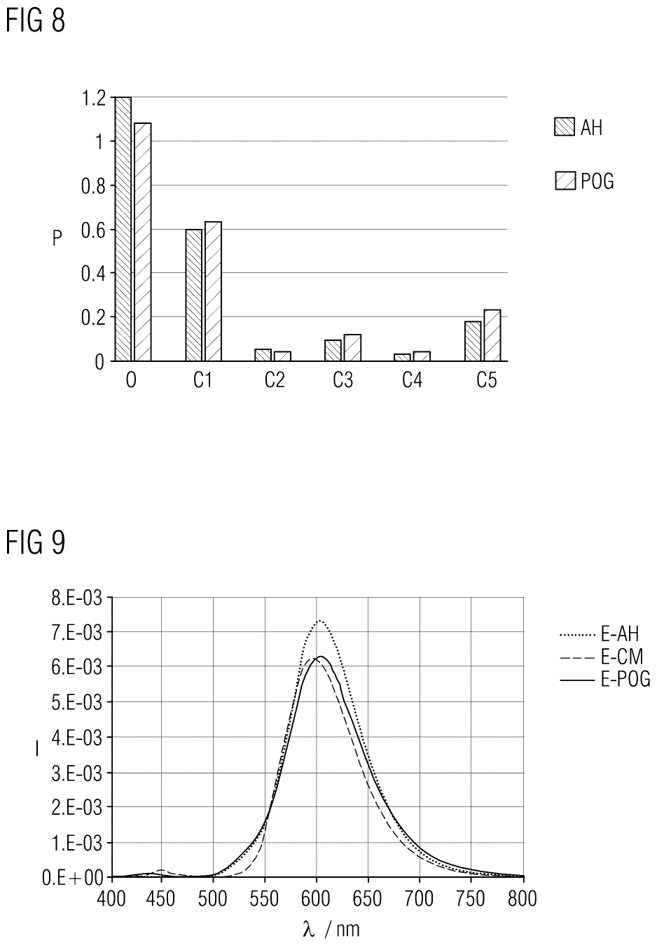

FIG. 8 shows simulated power losses for different loss channels of a light emitting component according to an exemplary embodiment and a comparative example.

FIG. 9 shows emission spectra of light emitting components according to an exemplary embodiment and comparative examples.

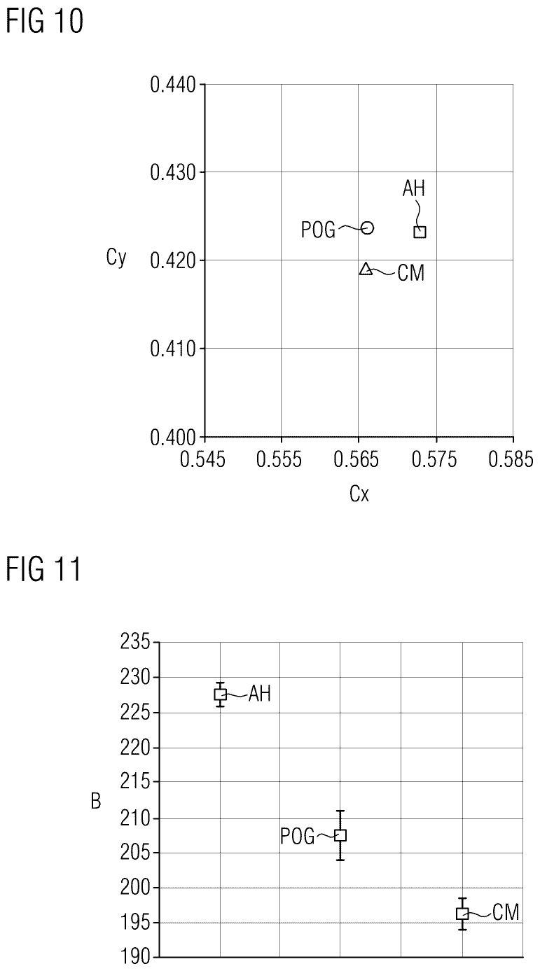

FIG. 10 shows color coordinates of light emitting components according to an exemplary embodiment and comparative examples.

FIG. 11 shows a brightness of light emitting components according to an exemplary embodiment and comparative examples.

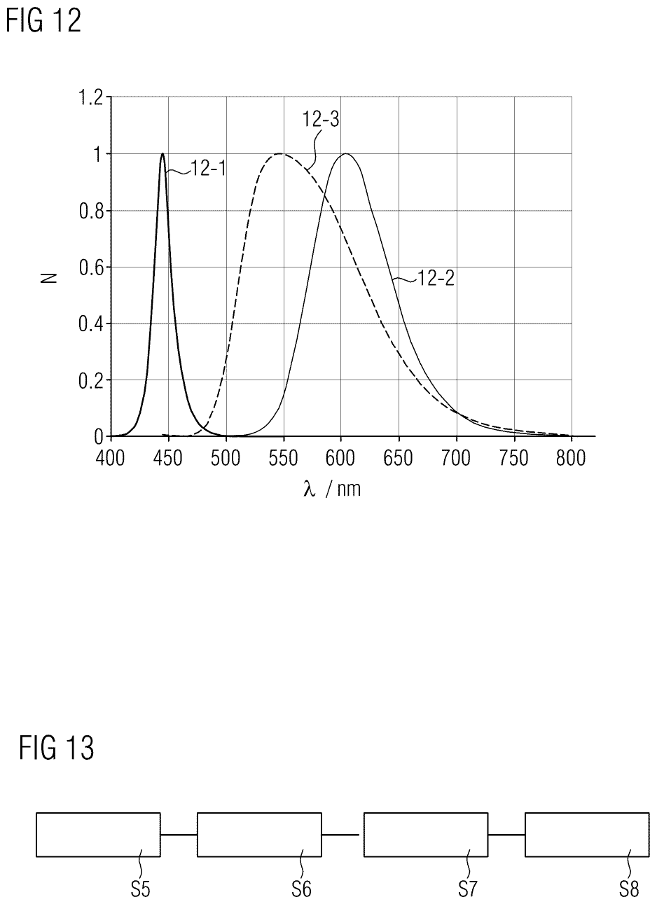

FIG. 12 shows wavelength ranges for a first wavelength range, a second wavelength range, and a second wavelength range.

FIG. 13 schematically shows steps of a method for producing a conversion element.

In the exemplary embodiments and figures, similar or similarly acting constituent parts are provided with the same reference symbols. The elements illustrated in the figures and their size relationships among one another should not be regarded as true to scale. Rather, individual elements may be represented with an exaggerated size for the sake of better representability and/or for the sake of better understanding.

The exemplary embodiment of a conversion element 1 shown in FIG. 1 comprises a first conversion layer 2. The first conversion layer 2 comprises a matrix material 4. A first phosphor 3 and a filler 5 are homogeneously distributed in the matrix material 4. The first phosphor 3 presently is (AE₁₋ₓEuₓ)₂Al₂Si₂N₆ with 0<x≤0.1, wherein AF is selected from the group consisting of Mg, Ca, Sr, Ba, and combinations thereof. The filler 5 is fumed silica in an amount of at most 30% compared to an amount of the matrix material 4. The matrix material 4 is a methyl polysiloxane made from a methyl methoxy polysiloxane with a methoxy content between and including 20 vols and 50 vol %, in particular between and including 30% and 40%. The first phosphor 3 comprises a volume fraction of about 27% in the matrix material 4. The first conversion layer 2 has a thickness of about 50 micrometers.

The conversion element 1 of FIG. 1 further comprises a second conversion layer 6. The second conversion layer 6 is presently a ceramic layer formed with (Y₁₋ₓCeₓ)₃Al₅O₁₂ Where 0<x≤0.1 as second phosphor 7 and having a porosity of between and including 0.02 vol % and 0.1 vol %. For example, the second conversion layer consists of Y₃Al₅O₁₂ with 2 vol % Ce. The second conversion layer comprises a thickness of about 175 micrometers.

An adhesive layer 8 is arranged between the first conversion layer 2 and the second conversion layer 6. The adhesive layer 8 comprises a silicone glue with a thickness between and including 4 micrometers and 8 micrometers.

The first conversion layer 2 is configured to convert electromagnetic radiation of a first wavelength range into electromagnetic radiation of a second wavelength range. The first wavelength range is in the blue spectral range, whereas the second wavelength range is in the red spectral range. The second conversion layer 6 is configured to convert electromagnetic radiation of the first wavelength range into electromagnetic radiation of a third wavelength range. The third wavelength range is in the yellow spectral range. The electromagnetic radiation of the second wavelength range and the electromagnetic radiation of the third wavelength range mix to give amber light having a color point within 0.55<Cx<0.6 and 0.4<Cy<0.45 in the CIE 1931 color space.

Presently, the conversion element 1 is configured for a full conversion of the electromagnetic radiation of the first wavelength range. That is only the electromagnetic radiation of the first wavelength range and the electromagnetic radiation of the second wavelength range can pass through the conversion element 1. In other words, no or negligible electromagnetic radiation of the first wavelength range leaves the conversion element 1.

FIG. 2 shows schematically steps of a method for producing a conversion element 1 according to an exemplary embodiment. In particular, the method for producing a conversion element 1 described in combination with FIG. 2 results in the conversion element 1 shown in FIG. 1.

In a first method step S1 a mixture comprising a first phosphor 3 and a precursor of a matrix material 4 are provided. The precursor of the matrix material 4 is presently a methyl methoxy polysiloxane with a methoxy content of between and including 30% and 40%. The mixture further comprises fillers 5. Presently, the filler 5 is fumed silica which is added in a range of between and including 0 wt % and 30 wt % compared to an amount of the precursor of the matrix material 4. The mixture is presently a slurry as the precursor of the matrix material 4 is in liquid form.

In a second method step S2, a second conversion layer 6 is provided. Presently, the second conversion layer 6 is provided in the form of a wafer such that a plurality of conversion elements 1 are produced by the method. However, it is also possible that the second conversion layer 6 is already shaped into a size of the final conversion element 1, seen in top view. The second conversion layer 6 presently comprises Y₃Al₅O₁₂ with 2 vol % Ce as second phosphor 7 and has a porosity between and including 0.02 vol % and 0.1 vol %. The second conversion layer 6 is configured to convert electromagnetic radiation of a first wavelength range into electromagnetic radiation of a third wavelength range. The first wavelength range is in the ultraviolet to blue spectral range, whereas the third wavelength range is in the yellow spectral range.

Furthermore, a curing agent in an amount of between and including 0.05 wt % and 5 wt % compared to the amount of the precursor of the matrix material 4 is added to the mixture. The curing agent is a titanium alkoxide, an amine-containing base or a combination thereof.

In a third method step S3, the mixture with the curing agent is applied on the second conversion layer 6. The mixture is applied using spraying, dispensing, or casting.

In a fourth method step S4, the mixture is cured such that a first conversion layer 2 is formed. During curing the precursor of the matrix material 4 polymerizes to form a three-dimensional network of a methyl polysiloxane. If the second conversion layer 6 is provided in the form of a wafer, individual conversion elements 1 are produced by singulating, for example by dicing. The first conversion layer 2 is configured to convert electromagnetic radiation of the first wavelength range into electromagnetic radiation of a second wavelength range which is presently in the red spectral range. The electromagnetic radiation of the second wavelength range and the electromagnetic radiation of the third wavelength range mix to give amber light.

In combination with FIG. 3 a light emitting component 9 according to an exemplary embodiment is disclosed. The light emitting component 9 comprises a conversion element 1 and a semiconductor chip 10 arranged in a cavity 15. The conversion element 1 is as described in combination with FIG. 1. However, compared to the conversion element 1 of FIG. 1, there is no adhesive layer 8 arranged between the first conversion layer 2 and the second conversion layer 6. However, it is also possible that an adhesive layer 8 is arranged between the first conversion layer 2 and the second conversion layer 6 as shown in combination with FIG. 1.

The conversion element 1 is arranged on the semiconductor chip 10 using a layer of glue 14. A thickness of the layer of the glue 14 is between and including 2 micrometers to 8 micrometers, for example about 5 micrometers. The conversion element 1 is arranged such that the first conversion layer 2 is closer to the semiconductor chip 10 than the second conversion layer 6. Seen in top view, the conversion element 1 has the same size as the semiconductor chip 10. In other words, a size of the conversion element 1 matches a size of the semiconductor chip 10 in top view.

The semiconductor chip 10 presently comprises a semiconductor layer sequence 11 which is epitaxially grown. The semiconductor layer sequence 11 comprises an active region 12 configured to generate electromagnetic radiation of a first wavelength range. The electromagnetic radiation of the first wavelength range is emitted through a radiation exit surface 13.

The electromagnetic radiation of the first wavelength range is converted by the first conversion layer 2 into electromagnetic radiation of a second wavelength range and by the second conversion layer 6 into electromagnetic radiation of a third wavelength range. The first wavelength range is in the ultraviolet to blue spectral region, the second wavelength range in the red spectral region, and the third wavelength range in the yellow spectral region. The electromagnetic radiation of the second wavelength range and the electromagnetic radiation of the third wavelength range mix to give amber light. Presently, the conversion element 1 is configured for full-conversion. That is the light emitting component 9 only emits amber light.

A mirror 16 is arranged in the semiconductor layer sequence 11 below the active region 12. The mirror 16 increases the efficiency of the light emitting component 9 as the electromagnetic radiation of the first wavelength range generated in the active region 12 and emitted in the direction away from the conversion element 1 is reflected towards the conversion element 1. Furthermore, the cavity 15 is filled with a reflective resin 17 such that the semiconductor chip 10 and conversion element 1 are surrounded by the reflective resin 17. The reflective resin 17 is diffuse reflective and comprises TiO₂ particles embedded in a silicone. The TiO₂ comprise a portion of about 35 vol % in the silicone. The reflective resin increases the efficiency of the light emitting component 9.

FIG. 4 shows an angular distribution D of departing photons inside a conversion element 1. Curve 4-1 results from a scattering event at one pore in a second conversion layer 6 with (Y₁₋ₓCeₓ)₃Al₅O₁₂. Curve 4-2 results from a scattering event at a phosphor particle in a first conversion layer 2. Curve 4-3 results from a conversion event. It can be seen from FIG. 4 that after a conversion event, a photon departs in any direction with equal probability. Scattering events, however, are highly directional. This means that conversion events are much more effective than scattering events in sending photons in an undesired direction. Thus, to achieve a high brightness of a light-emitting component 9 with the conversion element 1, a number of conversion events should be as small as possible. In other words, a high conversion efficiency is desired in the conversion element 1 as otherwise the number of conversion events increases. With an increased number of conversion events photons are more often sent in an undesired direction and thus the brightness of the light-emitting component 9 decreases.

FIG. 5 shows a simulation of a converted light C given in photons/s depending on the color coordinate Cx. Curve 5-1 results from the exemplary embodiment of a conversion element 1 described in combination with FIG. 1, whereas curve 5-2 results from a conversion element 1 according to a comparative example. The comparative example comprises a substrate on which a conversion layer with a first phosphor and a second phosphor in a polysiloxane is arranged.

FIG. 6 shows a simulation of a brightness B given in lumens depending on the color coordinate Cx. Curve 6-1 results from the exemplary embodiment of a conversion element 1 described in combination with FIG. 1, whereas curve 6-2 results from a conversion element 1 according to the comparative example described in combination with FIG. 6.

FIG. 7 shows a simulation of a conversion efficiency L given in lumens/(W optical blue) depending on the color coordinate Cx. Curve 7-1 results from the exemplary embodiment of a conversion element 1 described in combination with FIG. 1, whereas curve 7-2 results from a conversion element 1 according to the comparative example described in combination with FIG. 5.

FIGS. 5 to 7 show that the conversion element 1 described herein outperforms the conversion element 1 according to the comparative example in a broad range of the color coordinate Cx. A mean wavelength shift per photon at the color point of Cx=0.575 and Cy=0.42 is about 150 nanometers for the exemplary embodiment, whereas it is about 139 nanometers for the comparative example. The higher the mean wavelength shift per photon is, the more conversion is achieved with the fewest conversion events. This means, the higher the mean wavelength shift per photon, the more efficient is the conversion element.

The difference in the mean wavelength shift per photon between the exemplary embodiment and the comparative example enables the conversion element 1 according to the exemplary embodiment to reach the desired amber color point with a significantly smaller number of conversion events. Thus, losses of photons and therefore a loss of brightness is reduced in the conversion element 1 according to the exemplary embodiment. The conversion element 1 according to the exemplary embodiment has a simulated brightness advantage of about 11% in photons and of about 12% in lumens at the desired amber color point compared to the conversion element 1 of the comparative example.

FIG. 8 shows simulated power losses for different loss channels C1 to C5 of light emitting components 9. The power losses P are given in Watts. Bars AH result from a light emitting component 9 according to the exemplary embodiment shown in FIG. 3. Bars POG result from a light emitting component 9 according to a first comparative example. Compared to the exemplary embodiment, the light emitting component 9 of the first comparative example comprises a different conversion element 1. The conversion element 1 of the first comparative example comprises a substrate of glass on which a layer with a first phosphor 3 and a second phosphor 7 in a polysiloxane is arranged.

The loss channel C1 is associated with the conversion in the conversion element 1 of the light emitting components 9. The loss channel C2 derives from the reflective resin 17 which surrounds the semiconductor chip 10 and the conversion element 1 in the light emitting components 9. The loss channel C3 is associated with a base of the semiconductor chip 10. A pad on top of the semiconductor chip 10 results in the loss channel C4. The loss channel C5 derives from a distributed Bragg reflector (DBR) such as the mirror 16 of the semiconductor chip 10.

The lower losses at the loss channel C5 in the light emitting component 9 according to the exemplary embodiment are a result of the arrangement of the conversion element 1 wherein the first conversion layer 2 comprising the first phosphor 3 is closer to the radiation exit surface 13 of the semiconductor chip 10. This is because a reabsorption of the second wavelength range is reduced.

The bars O in the leftmost position in FIG. 8 show a light output of the light emitting components 9. The light emitting component 9 of the exemplary embodiment has a significantly higher light output than the light emitting component 9 of the first comparative example. This is because losses at the loss channels C1 to C5 are overall lower in the light emitting component 9 of the exemplary embodiment than in the light emitting component 9 of the first comparative example.

FIG. 9 shows emission spectra E-AH, E-CM, and E-POG of light emitting components 9. The emission spectrum E-AH results from the light emitting component 9 of the exemplary embodiment shown in FIG. 3. The emission spectrum E-POG results from a light emitting component 9 of the first comparative example. The structure of the first comparative example was already described in combination with FIG. 8. The emission spectrum E-CM results from a light emitting component 9 of a second comparative example having a conversion element 1 which is ceramic and without a conversion layer comprising a phosphor embedded in a matrix material.

In FIG. 9 a spectral power density I given in W/nm is plotted against a wavelength λ of the electromagnetic radiation given in nanometers emitted by the light emitting components 9. The light emitting component 9 of the exemplary embodiment shows a higher irradiance at a maximum of the corresponding emission spectrum E-AH than the first comparative example and the second comparative example. However, the maximum of each of the emission spectra E-AH, E-CM, and E-POG is in the same wavelength region around 600 nanometers. This assures that the desired color point is achieved with all three examples.

Further properties of the light emitting component 9 according to the exemplary embodiment of FIG. 3 and the previously described first and second comparative example are shown in FIGS. 10 and 11. In both figures the data points AH corresponds to the exemplary embodiment, the data points POG to the first comparative example and the data points CM to the second comparative example. The data point of FIGS. 10 to 12 are an average of ten samples each of the exemplary embodiment as well as the first and second comparative example.

FIG. 10 shows color coordinates Cx and Cy of the light emitting components 9. It can be seen from this figure that the color coordinates of the light emitting components 9 of the exemplary embodiment, the first comparative example, and the second comparative example are all in the same range.

FIG. 11 shows a brightness B of the light emitting components 9 given in lumens. The brightness values are obtained by measuring five to ten light emitting components 9 of each the exemplary embodiment, the first comparative example, and the second comparative example. The error bars represent 95% confidence intervals.

As can be seen from FIGS. 10 and 11, the brightness B of the light emitting component 9 according to the exemplary embodiment is significantly higher than the brightness B of the light emitting components 9 according to the comparative examples, even though the color points of the light emitting components 9 are similar. In particular, a brightness gain for the exemplary embodiment is found to be around 10% compared to the first comparative example.

FIG. 12 shows wavelength ranges for a first wavelength range 12-1, a second wavelength range 12-2, and a third wavelength range 12-3. A normalized power density N depending on the wavelength λ in nm is shown.

The first wavelength range 12-1 comprises wavelengths from about 400 nanometers to about 500 nanometers. The second wavelength range 12-2 comprises wavelengths from about 525 nanometers to about 775 nanometers. The third wavelength range 12-3 comprises wavelengths from about 475 nanometers to about 775 nanometers. The first wavelength range 12-1 is emitted by a semiconductor chip 10. The second wavelength range 12-2 arises from a first conversion layer 2 with a first phosphor 3. The third wavelength range 12-3 arises from a second conversion layer 6 with a second phosphor 7. It can be seen from FIG. 12 that an emission maximum of the first phosphor 3 is at higher wavelengths than an emission maximum of the second phosphor 7.

Another exemplary embodiment of the method for producing a conversion element is shown in FIG. 13. In a first method step S5 a first conversion layer 2 is provided. For this, a mixture of a first phosphor 3 and a precursor of a matrix material 4 is provided and cured to form the first conversion layer 1. That is, the first conversion layer 2 is produced separately from a second conversion layer 6. In particular, the first conversion layer 2 is provided in the form of a wafer or a sheet. For example, the first phosphor 3 is (AE₁₋ₓEuₓ)₂Al₂Si₂N₆ with 0<x≤0.1, wherein AE is selected from the group consisting of Mg, Ca, Sr, Ba, and combinations thereof.

In a second method step S6, the second conversion layer 6 is provided. The second conversion layer 6 is provided in the form of a wafer. The second conversion layer 6 comprises a second phosphor 7. The second phosphor 7 is presently (Y₁₋ₓCeₓ)₃Al₅O₁₂ where 0<x≤0.1.

An emission maximum of the first phosphor is at higher wavelengths than an emission maximum of the second phosphor. Presently, the second conversion layer 6 is a ceramic layer. An adhesive layer 8 is applied on the second conversion layer 6.

In a third method step S7, the first conversion layer 2 is applied on the adhesive layer 8 and therefore on the second conversion layer 6. Thus, the adhesive layer 8 is arranged between the first conversion layer 2 and the second conversion layer 6. The adhesive layer 8 is in direct contact with the first conversion layer 2 and the second conversion layer 8. The first conversion layer 2 and the second conversion layer 8 are glued together by means of the adhesive layer 8.

In a fourth method step S8, individual conversion elements 1 are formed by singulating the wafer of the second conversion layer 6 and the first conversion layer 2.

The features and exemplary embodiments described in connection with the figures can be combined with each other according to further exemplary embodiments, even if not all combinations are explicitly described. Furthermore, the exemplary embodiments described in connection with the figures may have alternative or additional features as described in the general part.

This patent application claims the priority of U.S. provisional patent application 63/411,436, the disclosure content of which is hereby incorporated by reference.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

### REFERENCES

1 conversion element
2 first conversion layer
3 first phosphor
4 matrix material
5 filler
6 second conversion layer
7 second phosphor
8 adhesive layer
9 light emitting component
10 semiconductor chip
11 semiconductor layer sequence
12 active region
13 radiation exit surface
14 glue
15 cavity
16 mirror
17 reflective resin
θ angle
λ wavelength
Cx, Cy color coordinates
B brightness
C converted light
C1 to C5 loss channels
D angular distribution
E emission spectrum
I spectral power density
L conversion efficiency
N normalized power density
O output
P power
S1 to S8 method steps
AH exemplary embodiment
POG, CM comparative examples

1. A conversion element comprising
a first conversion layer with a first phosphor embedded in a matrix material, said first conversion layer configured to convert electromagnetic radiation of a first wavelength range into electromagnetic radiation of a second wavelength range, and
a second conversion layer with a second phosphor, said second conversion layer configured to convert electromagnetic radiation of the first wavelength range into electromagnetic radiation of a third wavelength range,
wherein an emission maximum of the first phosphor is at higher wavelengths than an emission maximum of the second phosphor, and
wherein the conversion element is configured for full-conversion of the first wavelength range.

2. The conversion element according to claim 1,
wherein the second wavelength range is in the red spectral range,
wherein the third wavelength range is in the yellow spectral range, and
wherein the electromagnetic radiation of the second wavelength range and the electromagnetic radiation of the third wavelength range mix to give amber light.

3. The conversion element according to claim 2, wherein the amber light corresponds to a color point within 0.55<Cx<0.6 and 0.4<Cy<0.45 in the CIE 1931 color space.

4. The conversion element according to claim 1, wherein the first wavelength range is in the blue spectral range.

5. The conversion element according to claim 1, further comprising an adhesive layer between the first conversion layer and the second conversion layer.

6. The conversion element according to claim 1, wherein a thickness of the conversion element is between and including 70 micrometers and 320 micrometers.

7. The conversion element according to claim 1, wherein the matrix material comprises or consists of a cured polysiloxane.

8. The conversion element according to claim 7, wherein a siloxane bonding in the cured polysiloxane is at least 85% T-unit type.

9. The conversion element according to claim 1, wherein a volume fraction of the first phosphor in the matrix material is between and including 20% and 50%.

10. The conversion element according to claim 1,
wherein the second conversion layer is a ceramic layer.

11. The conversion element according to claim 1,
wherein the first phosphor is a Eu-based phosphor, and
wherein the second phosphor is a Ce-based phosphor.

12. The conversion element according to claim 1,
wherein the first conversion layer comprises additives selected from the group consisting of thickeners, filler and combinations thereof.

13. A method for producing a conversion element comprising
providing a first conversion layer with a first phosphor embedded in a matrix material, said first conversion layer configured to convert electromagnetic radiation of a first wavelength range into electromagnetic radiation of a second wavelength range,
providing a second conversion layer with a second phosphor, said second conversion layer configured to convert electromagnetic radiation of the first wavelength range into electromagnetic radiation of a third wavelength range, and
applying the first conversion layer on the second conversion layer,
wherein an emission maximum of the first phosphor is at higher wavelengths than an emission maximum of the second phosphor, and
wherein the conversion element is configured for full-conversion of the first wavelength range.

14. The method according to claim 13,
wherein the method further comprises applying an adhesive layer on the second conversion layer.

15. The method according to claim 13,
wherein providing the first conversion layer comprises
providing a mixture of a precursor of a matrix material and a first phosphor and
curing the mixture to form the first conversion layer.

16. The method according to claim 13,
wherein a curing agent is added to the mixture before curing the mixture.

17. The method according to claim 13,
wherein providing the first conversion layer and applying the first conversion layer are performed simultaneously.

18. The method according to claim 13,
wherein the matrix material is a polysiloxane, and
wherein the precursor of the matrix material is a methyl methoxy polysiloxane with a methoxy content between and including 10 vol % and 50 vol %.

19. A light emitting component comprising
a semiconductor chip configured to emit electromagnetic radiation of a first wavelength range through a radiation exit surface, and
a conversion element according to claim 1 comprising a first conversion layer and a second conversion layer,
wherein the conversion element is arranged on the radiation exit surface.

20. The light emitting component according to claim 19,
wherein the first conversion layer is arranged closer to the radiation exit surface than the second conversion layer.
